(19) United States
(12) Patent Application Publication
(10) Pub. No.: US 2011/0182701 A1
(43) Pub. Date: Jul. 28, 2011

(54) METHOD AND APPARATUS FOR TRANSFERRING DIE FROM A WAFER

(75) Inventors: Sean M. Adams, Rochester, NY (US); Koenraad Alexander Gieskes, Deposit, NY (US)

(73) Assignee: UI HOLDING CO., Conklin, NY (US)

(21) Appl. No.: 13/014,395

(22) Filed: Jan. 26, 2011

Related U.S. Application Data
(60) Provisional application No. 61/299,066, filed on Jan. 28, 2010.

(51) Int. Cl. H01L 21/677

(52) U.S. Cl. 414/222.01; 414/806

(57) ABSTRACT

Disclosed herein is a method for transferring die from a wafer that includes picking two or more die from a wafer using a multi-spindle picking head, wherein the multi-spindle picking head is rotatable. The method includes moving the multi-spindle picking head from the wafer feeder to a placement machine, and presenting the two or more picked die to the placement machine for subsequent placement. Further disclosed herein is an apparatus for transferring die from a wafer that includes a picking head with a plurality of spindles. Each spindle is configured to pick a die from a wafer of die. The multi-spindle picking head is rotatable and moveable in at least one direction.

### RELATED APPLICATION

The present invention is a non-provisional claiming priority to a commonly owned U.S. Provisional Patent Application Ser. No. 61/299,066 filed Jan. 28, 2010, of Adams et al., entitled “METHOD AND APPARATUS FOR TRANSFERRING DIE FROM A WAFER,” the disclosure of which is herein incorporated by reference to the extent not inconsistent with the present disclosure.

### TECHNICAL FIELD

This disclosure relates generally to the manufacture of printed circuit boards, semiconductor packages, and/or system in packages. More particularly, the disclosure relates to the delivery of semiconductor components (commonly referred to as “die” or “chips”) from a wafer to a substrate.

### BACKGROUND

In the semiconductor electronics assembly industry, diced wafers are typically provided on a sticky film held in a metal ring commonly referred to as a “wafer frame” with the face of the die up. These films are stretchable to separate the diced die prior to removal from the wafer. Delivery of die from the wafer to a substrate often includes a wafer feeder machine and a placement machine. The standard wafer feeder machine includes a single-spindle picking head to pick the die from the wafer with a vacuum or suction process. The die may then be placed onto a shuttle plate or other transportation mechanism that brings the die from the wafer feeder machine to the placement machine. The die may be rotated by the single-spindle picking head in the case that the shuttle plate is oriented on a different plane than the wafer. For example, the wafer may be oriented vertically (i.e. on a plane that is perpendicular to the ground), and the shuttle plate may be oriented horizontally (i.e. on a plane that is parallel to the ground). The shuttle plate then supplies the die to a single or multi-spindle placement head of the placement machine.

It is sometimes necessary to “flip” a die 180 degrees such that the die faces the opposite direction than would be provided with a “direct” hand-off from the single-spindle picking head to the shuttle plate. Known wafer feeder machines accomplish this “flip” by providing an interposer component between the single-spindle picking head and the shuttle plate. This interposer component is configured to receive the die from the single-spindle picking head in the opposite, “flipped,” direction than the shuttle plate would receive the die from the single-spindle picking head directly. This is accomplished by rotating the single-spindle picking head in a similar manner to the above-described case where the shuttle plate is oriented on a different plane than the wafer.

Thus, in a typical “direct” transfer process there are three hand-offs from the wafer to the placement machine: (1) from the wafer to the single-spindle picking head; (2) from the single-spindle picking head to the shuttle plate; and (3) from the shuttle plate to the single or multi-spindle placement head of the placement machine Likewise, in a typical transfer process requiring a “flip,” there are four hand-offs from the wafer to the placement machine: (1) from the wafer to the single-spindle picking head; (2) from the single-spindle picking head to the interposer; (3) from the interposer to the shuttle plate; and (4) from the shuttle plate to the single or multi-spindle placement head of the placement machine. The multi-spindle placement head of placement machine may then subsequently place the picked die on a substrate.

It is also known to integrate the wafer feeder machine and the placement machine into a single pick and place machine. In this case, a single-spindle picking head picks the die from the wafer. The single-spindle picking head is configured to rotate 180 degrees and directly presents the die “flipped” with the face down to a single-spindle placement head. The wafer in such machines is often configured to move in an X and a Y direction, allowing the single-spindle picking head to remain stationary during the picking process. These integrated pick and place machines include two hand-offs from the wafer to the placement head: (1) from the wafer to the single-spindle picking head; and (2) from the single-spindle picking head to the single-spindle placement head. The single-spindle placement head may then subsequently place the picked die on a substrate.

Multiple die hand-offs make the process less reliable, especially in the case of smaller chips. In addition to reliability, increased placement speed reduces cost and increases output of a pick and place process. Therefore, a method and apparatus for transferring die from a wafer to a substrate that retains placement speed with minimal hand-offs would be well received in the art.

### SUMMARY

According to one aspect, a method for transferring die from a wafer to a placement machine comprises: a) picking two or more die from the wafer using a multi-spindle picking head, wherein the multi-spindle picking head is rotatable; b) moving the multi-spindle picking head from the wafer to the placement machine; and c) presenting the two or more picked die to the placement machine for subsequent placement.

According to another aspect, an apparatus for transferring die from a wafer to a placement machine comprises: a picking head comprising a plurality of spindles, each spindle configured to pick a die from the wafer of die, wherein the multi-spindle picking head is rotatable and moveable in at least one direction.

According to another aspect, a method for transferring die from a wafer to a placement machine comprises: a) picking two or more die from the wafer located within the placement machine using a multi-spindle picking head, wherein the multi-spindle picking head is rotatable and the wafer is moveable; and b) presenting the two or more picked die to the placement machine for subsequent placement.

According to still another aspect, an apparatus for transferring die from a wafer to a placement machine comprises: a picking head comprising a plurality of spindles, each spindle configured to pick a die from the wafer of die, wherein the multi-spindle picking head is rotatable and the wafer of die is moveable in at least one direction.

### BRIEF DESCRIPTION OF THE DRAWINGS

FIG. 1A depicts a front perspective view of a wafer feeder machine and a placement machine, in accordance with one embodiment.

FIG. 1B depicts a rear perspective view of the wafer feeder machine and the placement machine of FIG. 1A, in accordance with one embodiment.

FIG. 2 depicts a top sectional view of the wafer feeder machine and placement machine of FIG. 1, with a multi-spindle picking head of the wafer feeder machine in a location to pick die from a wafer, in accordance with one embodiment.

FIG. 3 depicts a top sectional view of the wafer feeder machine and placement machine of FIGS. 1-2, with the multi-spindle picking head of the wafer feeder machine in a location to place die on a transfer plate for subsequent presentation to the placement machine, in accordance with one embodiment.

FIG. 4 depicts a perspective view of a portion of the wafer feeder machine of FIGS. 1-3 with a multi-spindle picking head in a location to pick die from a wafer, in accordance with one embodiment.

FIG. 5 depicts a perspective view of a portion of a wafer feeder machine FIGS. 1-4 with the multi-spindle picking head in a location to place die on a transfer plate for subsequent presentation to a placement machine, in accordance with one embodiment.

FIG. 6 depicts a perspective view of a portion of a wafer feeder machine FIGS. 1-5 with the transfer plate in a location to present die to a placement machine, in accordance with one embodiment.

FIG. 7 depicts a perspective view of a portion of a wafer feeder machine FIGS. 1-6 with the multi-spindle picking head in a location and rotated to present die to a placement machine, in accordance with one embodiment.

### DETAILED DESCRIPTION

A detailed description of the hereinafter described embodiments of the disclosed apparatus and method are presented herein by way of exemplification and not limitation with reference to the Figures.

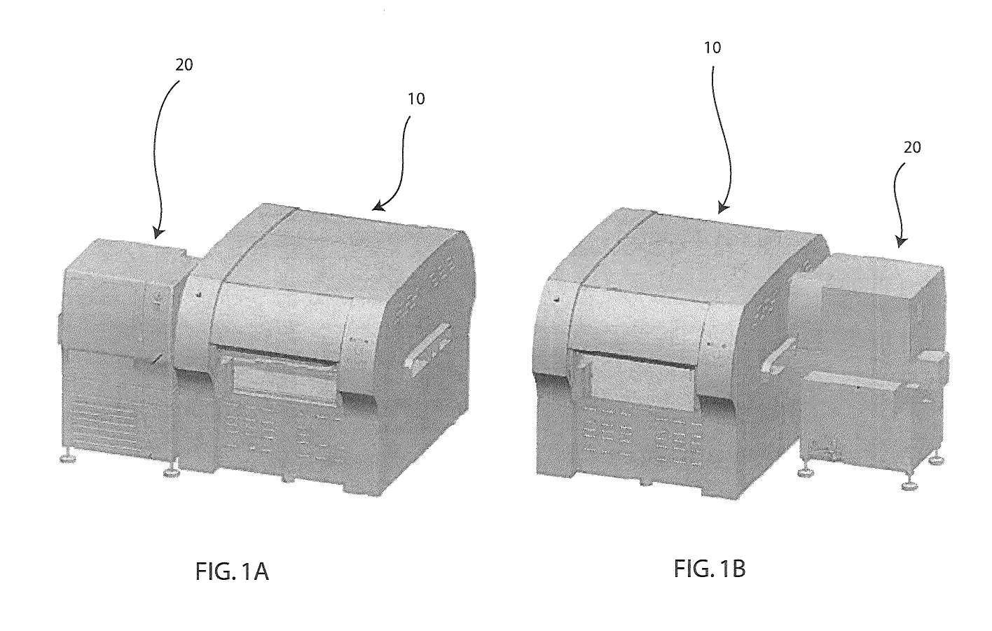

Referring firstly to FIGS. 1A and 1B, a placement machine 10 and wafer feeder machine 20 are shown. Particularly, FIG. 1A shows a front view of the placement machine 10 and wafer feeder machine 20 combination, while FIG. 1B shows a rear view. The wafer feeder machine 20 is configured to receive one or more wafers, upon which a plurality of die are disposed. The placement machine 10 is configured to receive one or more substrates upon which die are to be placed. The placement machine 10 and the wafer feeder machine 20 are in operable communication such that the die are transferred from the wafer feeder machine 20 to the placement machine 10 where the die may be placed on a substrate. The following description will explain this transferring system in detail.

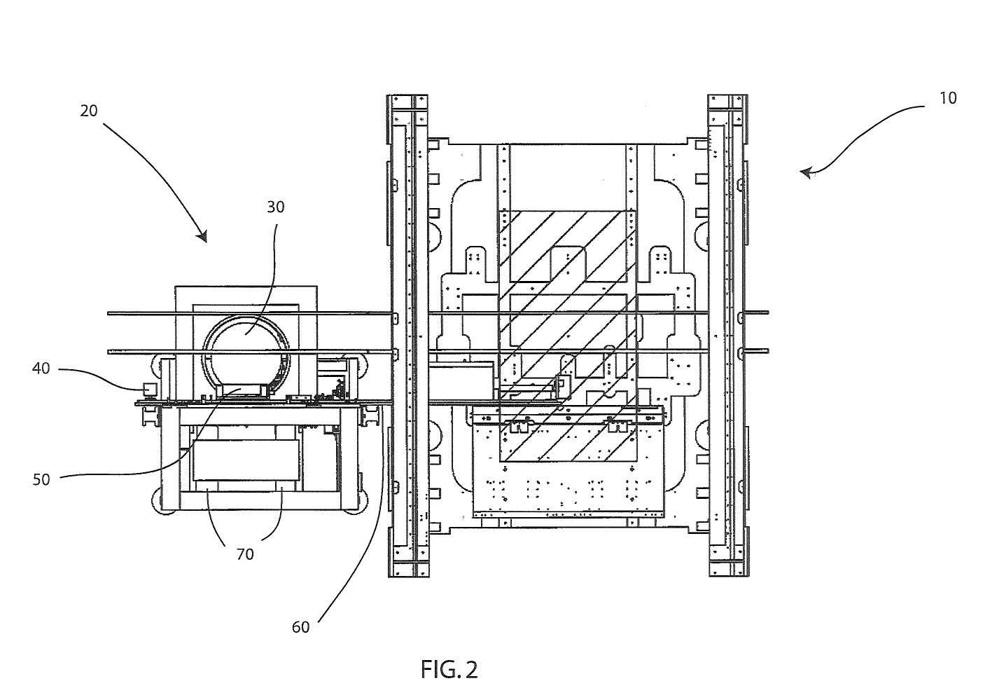

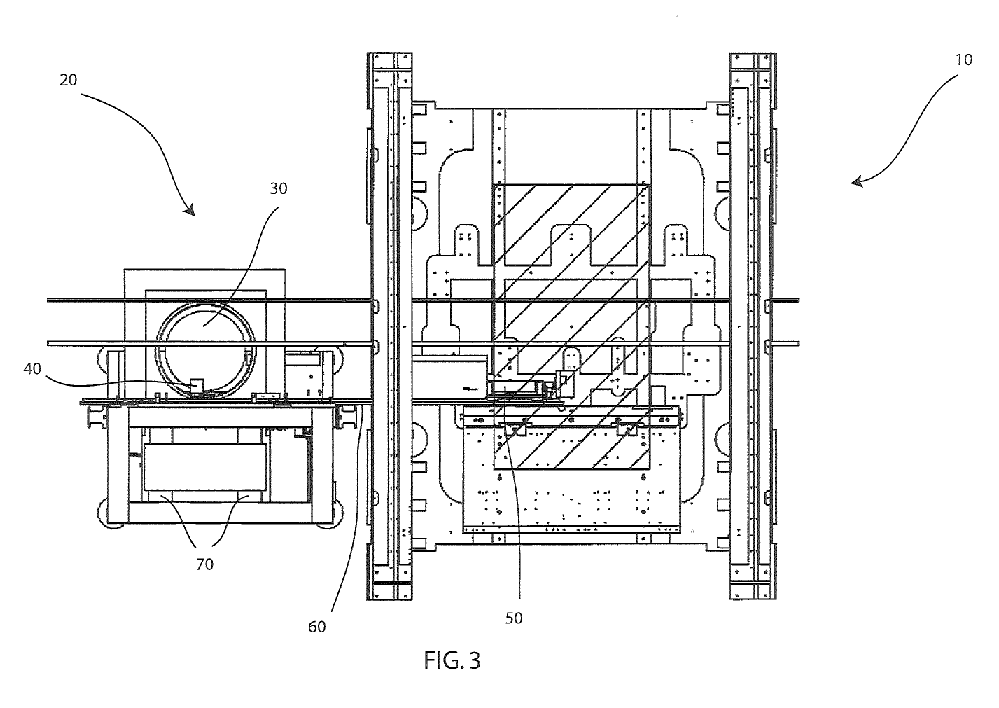

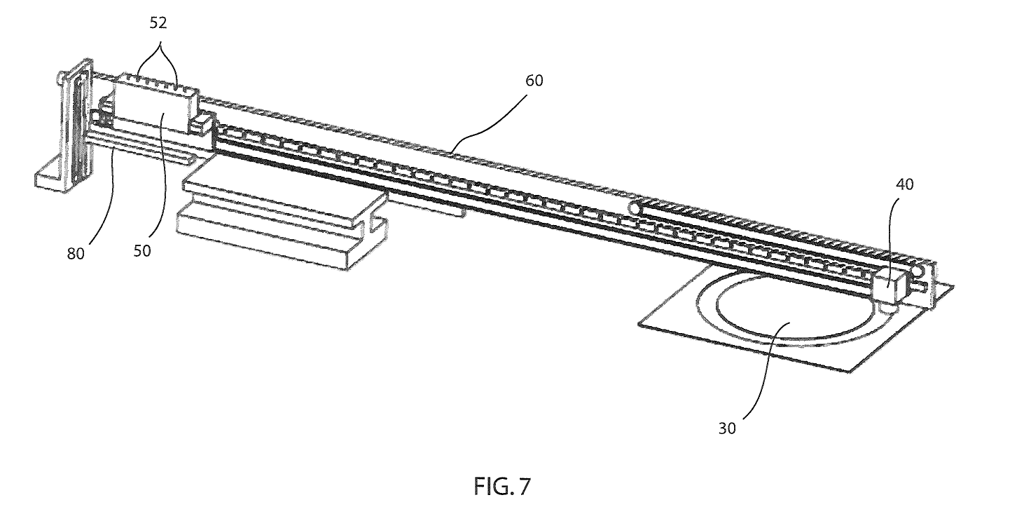

Referring now to FIGS. 2-3 top sectional views of the placement machine 10 and wafer feeder machine 20 are shown housing the a wafer 30. The wafer feeder machine 20 includes a picking head 50 that has includes a plurality of spindles 52 (shown in FIG. 7), each of which is configured to pick up a die from the wafer 30. It should be understood that the picking head 50 may be referred to as a multi-spindle picking head because it includes a plurality of spindles. Furthermore, each spindles 52 may be referred to as nozzles, valves, suctions, or the like. In any event, the spindles 52 may contact the die that is to be picked up, and create a vacuum suction force on the die such that the die remains attached to the spindle 52 for movement as will be apparent to those skilled in the art.

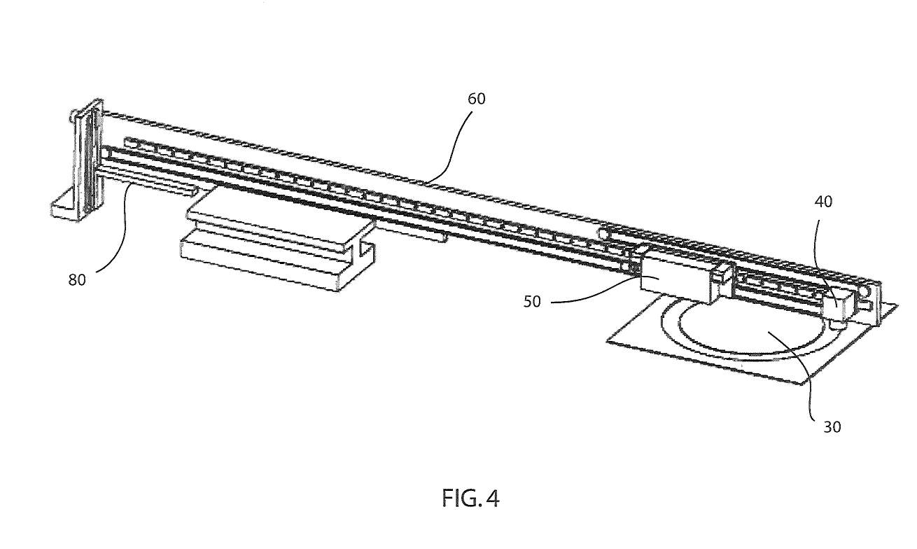

In one embodiment, the wafer 30 is moveable in a Y-direction along a Y-rail 70, while the multi-spindle picking head 50 is moveable in an X-direction along an X-rail 60. After one or more of spindles 52 of the multi-spindle picking head 50 have picked a die from the wafer, the multi-spindle picking head 50 may move along the X-rail 60 from the wafer feeder machine 20 to the placement machine 10 to the location shown in FIG. 3. At this location, the multi-spindle picking head 50 may present the die to either a transfer plate 80 (shown in FIGS. 4-7) or directly to a placement head (not shown) of the placement machine 10, as described herein below.

FIG. 4 shows a portion of the wafer feeder 20 and the multi-spindle picking head 50 at a location picking up the die from the wafer 30. The wafer feeder 20 may further include a camera 40 to improve accuracy and precision of the picking by the picking head 50. Camera 40 may also identify good/bad die to ensure only good die are picked by picking head 50. Ideally, these processes performed by camera 40 occur concurrently while picking head 50 is transferring the picked die. It should be understood that the combination of the Y-rail 70 of the wafer 30, and the X-rail 60 of the picking head 50 allows the picking head 50 to be positioned above any location on the wafer 30. Furthermore, the picking head 50 is shown (in FIG. 7) having seven spindles 52 to pick up to seven die. However, the invention is not limited to this embodiment and that any number of spindles 52 is contemplated. For example, the picking head 50 may include a single spindle, or may include a much greater number of spindles 52 than are shown in the Figures.

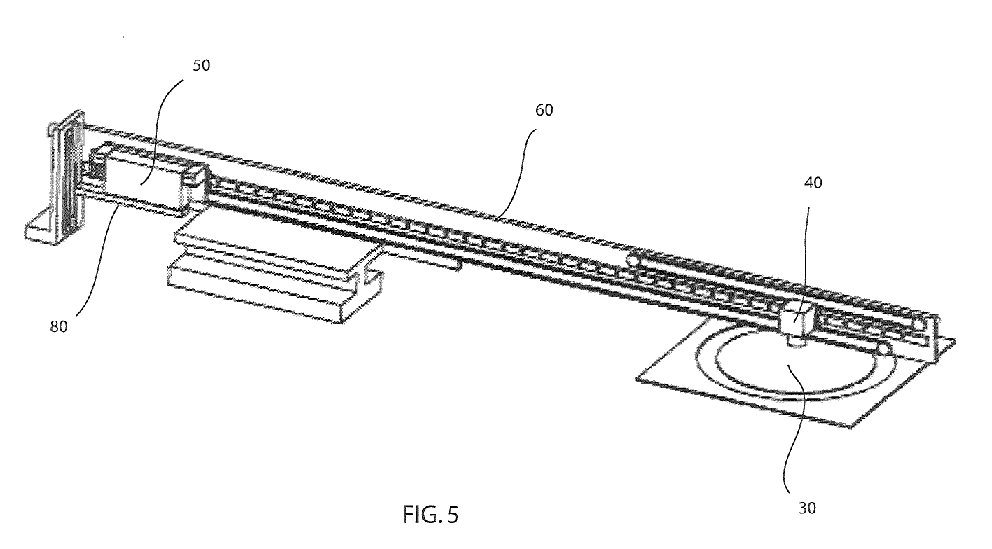

Referring now to FIG. 5, the multi-spindle picking head 50 is shown after moving along the X-rail distal to the wafer 30 to the placement machine 10. It should be understood that this was the location of the multi-spindle picking head 50 shown in FIG. 3. The picking head 50 is shown with the spindles 52 facing downwards toward the transfer plate 80. The transfer plate 80 may include a plurality of spindles (not shown) or other vacuum or suction mechanism that works in conjunction with the suction of the spindles 52 of the picking head 50. The spindles 52 may thereby safely and accurately transfer the die to the transfer plate 80. It should be understood that the transfer of each individual picked die may occur simultaneously or individually. After such a transfer, the multi-spindle picking head 50 may then return to the wafer 30 along the X-rail 60 pick another set of die.

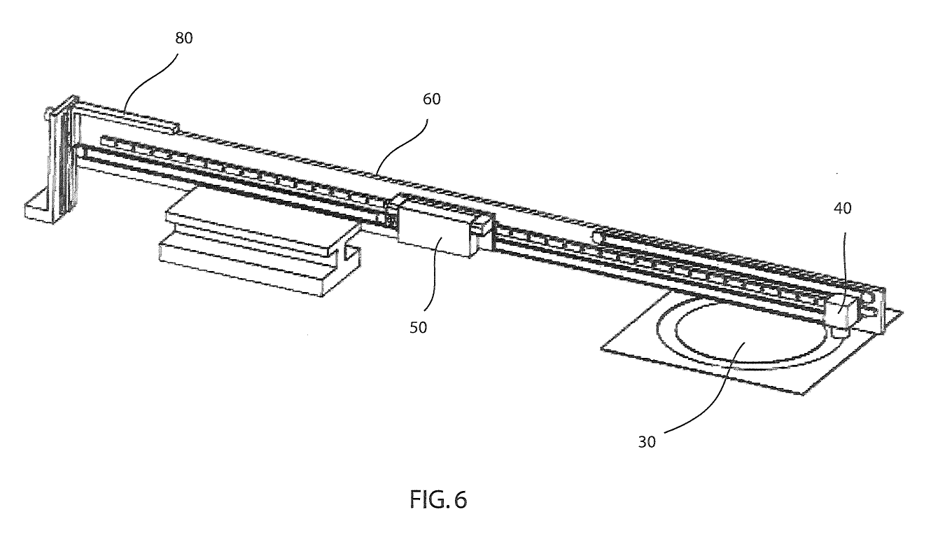

Once the die are received by the transfer plate 80, the transfer plate 80 may then lift the die to a position where a multi-spindle placement head (not shown) may receive the die for placement onto a substrate (not shown). This lifted position is shown in FIG. 6. Thus, the transfer plate may be moveable upward with respect to a ground, and in a direction that is perpendicular to both the X-rail 60 and the Y-rail 70.

FIG. 7 shows another embodiment of the process whereby the multi-spindle picking head 50 may transfer the die directly to a multi-spindle placement head (not shown) of the placement machine 10. In order to accomplish this, the multi-spindle picking head 50 may be configured to rotate about the X-rail 60 (or an axis that is parallel to the X-rail 60), such that the spindles 52 face upward. In the embodiment depicted, this is a 180 degree rotation. It should be understood that this rotation accomplishes a “flip” of the die without making additional transfers to an interposer which might decrease reliability.

In this “flip” embodiment, the die may start on the wafer 30 face up. The multi-spindle picking head 50 may then pick the die from the wafer 30 and move down the X-rail 60. The multi-spindle picking head 50 may then rotate 180 degrees such that the solder is facing down when the transfer is made to the multi-spindle placement head of the placement machine 10. It should be understood that this may reduce the number of hand-offs from four (as described hereinabove with respect to the prior art) to two in “flip” applications. Thus, the need for a separate interposer component may be eliminated. Furthermore, it should be understood that the rotation of the multi-spindle picking head 50 may occur while the picking head 50 is moving along the X-rail 60 such that the rotation is already completed when the picking head 50 reaches the placement machine 10.

Alternately, in the case where the transfer plate 80 is utilized, the die still may start face up on the wafer 30. The multi-spindle picking head 50 may then pick the die from the wafer 30 and move along the X-rail 60 toward the placement machine 10. In this case, the die is provided to the transfer plate 80 still facing up. Likewise, the transfer plate 80 is lifted to provide the die to the multi-spindle placement head still face up, for example in a wire bonding assembly process.

It should be understood that the location at which the transfer plate 80 lifts the die may be the precise (or substantially precise) location at which the multi-spindle picking head 50 provides the die to the multi-spindle placement head. Thus, in an embodiment where the transfer plate 80 is lift-able, as shown in the Figures, the multi-spindle placement head of the placement machine 10 may not be configured to move vertically. However, it is contemplated that the transfer plate 80 may remain stationary. In this embodiment, the multi-spindle placement head of the placement machine 10 may be configured to vertically move along an axis that is perpendicular to both the X-rail 60 and the Y-rail 70 to retrieve the die from the transfer plate 80.

Furthermore, it should be understood that the spacing of the spindles 52 along the length of the multi-spindle picking head 50 may be the same (or substantially the same) as the spacing of the spindles of the multi-spindle placement head. This may allow a “gang pick” whereby each of the die may be picked by the multi-spindle placement head from the multi-spindle picking head 50 in one stroke at the same time.

It is also contemplated that the wafer feeder machine 20 is integrated into the placement machine 10. In this embodiment, the multi-spindle picking head 50 may be mounted stationary over the wafer 30 and the wafer 30 may be mounted such that it can move in both the X and Y direction. It should also be understood that the embodiment contemplates that the wafer may be configured to move in both the X and Y direction even if the wafer feeder machine 20 and the placement machine 10 are separate. Likewise, the multi-spindle picking head 50 may still be configured to move in the X or Y direction, or both, in the case that the wafer feeder machine 20 is integrated into the placement machine 10.

Moreover, it is contemplated that the wafer 30 may be presented both horizontally, as shown in the Figures, or vertically (not shown). In the case that the wafer 30 is presented vertically, the multi-spindle picking head 50 may be configured to rotate 90 degrees about the X-rail 60 such that the spindles 52 are oriented to face the vertically oriented wafer 30 for picking. Again, the picking head 50 may the rotate 90 degrees up or 90 degrees down depending on whether the transfer to the placement head will be “direct” or “flipped.”

Further disclosed is a method for transferring die from a wafer to a placement machine, such as the placement machine 10. The method comprises picking two or more die from a wafer, such as the wafer 30 using a multi spindle picking head, such as the picking head 50. The multi spindle picking head may also be rotatable. Further, the method may comprise moving the multi-spindle picking head from the wafer to the placement machine. In another embodiment, the method may include moving the die in one or more directions from a first pick location to a second pick location. The method may then comprise presenting the two or more picked die to the placement machine for subsequent placement. Furthermore, the method may comprise rotating the multi-spindle picking head after picking the die from the wafer and before presenting the die to the placement machine. The method may also comprise rotating the multi-spindle picking head about an X-rail, such as the X-rail 60. The moving of the multi-spindle picking head may further occur along the X-rail. Moreover, the rotating of the multi-spindle picking head may occur substantially during the moving of the multi-spindle picking head. The method further may include transferring the two or more picked due from the multi-spindle picking head to a transfer plate, such as the transfer plate 80. The method may also include lifting the transfer plate from a downward position to an upward position.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments.

What is claimed is:

1. A method for transferring die from a wafer to a placement machine comprising:
a) picking two or more die from the wafer using a multi-spindle picking head, wherein the multi-spindle picking head is rotatable;
b) moving the multi-spindle picking head from the wafer to the placement machine; and
c) presenting the two or more picked die to the placement machine for subsequent placement.

2. The method for transferring die from a wafer to a placement machine as recited in claim 1, wherein the method further comprises:
(i) rotating the multi-spindle picking head after picking step (a) and before presenting step (c).

3. The method of transferring die from a wafer to a placement machine as recited in claim 2, further comprising rotating the multi-spindle picking head about an X-rail, wherein the moving step b) occurs along the X-rail.

4. The method for transferring die from a wafer to a placement machine as recited in claim 2, wherein said rotating step (i) occurs substantially during moving step (b).

5. The method for transferring die from a wafer to a placement machine as recited in claim 1, wherein said presenting step (c) further comprises:
ii) transferring the two or more picked die from the multi-spindle picking head to a transfer plate.

6. The method for transferring die from a wafer to a placement machine as recited in claim 5, wherein said transferring step (ii) further comprises:
iii) lifting the transfer plate from a downward position to an upward position.

7. An apparatus for transferring die from a wafer to a placement machine comprising:
a picking head comprising a plurality of spindles, each spindle configured to pick a die from the wafer of die, wherein the multi-spindle picking head is rotatable and moveable in at least one direction.

8. The apparatus for transferring die from a wafer to a placement machine as recited in claim 7, wherein the at least one direction is from the wafer into the placement machine whereby the picked die are transferable from the multi-spindle head to the placement machine.

9. The apparatus for transferring die from a wafer to a placement machine as recited in claim 7, further comprising a transfer plate located within the placement machine for placing the die picked by the multi-spindle head for subsequent removal by the placement machine.

10. The apparatus for transferring die from a wafer to a placement machine as recited in claim 7, wherein the transfer plate is liftable from a downward position to an upward position.

11. The apparatus for transferring die from a wafer to a placement machine as recited in claim 7, wherein the multi-spindle picking head rotates 180 degrees.

12. The apparatus for transferring die from a wafer to a placement machine as recited in claim 7, wherein the multi-spindle picking head rotates 90 degrees.

13. A method for transferring die from a wafer to a placement machine comprising:
a) picking two or more die from the wafer located within the placement machine using a multi-spindle picking head, wherein the multi-spindle picking head is rotatable and the wafer is moveable; and
b) presenting the two or more picked die to the placement machine for subsequent placement.

14. The method for transferring die from a wafer to a placement machine as recited in claim 13, wherein said picking step (a) further comprises:
i) moving the die in one or more directions from a first pick location to a second pick location.

15. The method for transferring die from a wafer to a placement machine as recited in claim 13, wherein said presenting step (b) further comprises:
ii) rotating the multi-spindle picking head.

16. An apparatus for transferring die from a wafer to a placement machine comprising:
a picking head comprising a plurality of spindles, each spindle configured to pick a die from the wafer of die, wherein the multi-spindle picking head is rotatable and the wafer of die is moveable in at least one direction.

17. The apparatus for transferring die from a wafer to a placement machine as recited in claim 16, wherein the at least one direction is along an X-axis.

18. The apparatus for transferring die from a wafer to a placement machine as recited in claim 16, wherein the at least one direction is along a Y-axis.

19. The apparatus for transferring die from a wafer to a placement machine as recited in claim 16, wherein the multi-spindle picking head rotates 180 degrees.

20. The apparatus for transferring die from a wafer to a placement machine as recited in claim 16, wherein the multi-spindle picking head rotates 90 degrees.
